(19) United States
(12) Patent Application Publication
(10) Pub. No.: US 2025/0389443 A1
(43) Pub. Date: Dec. 25, 2025

(54) AGENT BASED AIR PURIFICATION SYSTEM USING HYBRID PHYSICS-MACHINE LEARNING MODEL

(71) Applicants: University of California San Diego, La Jolla, CA (US); University of Massachusetts Amherst, Amherst, MA (US)

(72) Inventors: Tauhidur Rahman, San Diego, CA (US); M Tanjid Hasan Tonmoy, San Diego, CA (US); Forsad Al Hossain, Amherst, MA (US)

(73) Assignees: University of California San Diego, La Jolla, CA (US); University of Massachusetts Amherst, Amherst, MA (US)

(21) Appl. No.: 19/249,739

(22) Filed: Jun. 25, 2025

Related U.S. Application Data
(60) Provisional application No. 63/663,892, filed on Jun. 25, 2024.

(51) Int. Cl. F24F 11/63; F24F 8/22; F24F 120/14; G06F 30/28

(52) U.S. Cl. CPC F24F 11/63; F24F 8/22; G06F 30/28; F24F 2120/14

(57) ABSTRACT

In some embodiments, there is provided a system configured to receive an indication of an aerosol event at a first compartment of a room, wherein the room is divided into a plurality of compartments; receive, from at least one particulate measurement sensor located in the room and during a machine learning training phase, at least one particulate measurement for at least one compartment of the plurality of compartments of the room; train, during the machine learning training phase, a digital twin using aerosol event parameters comprising the indication of the aerosol event at the first compartment of the room and the at least one particulate measurement for the at least one of the plurality of compartments of the room; and provide the predicted concentration. Related methods, articles of manufacture, and systems are also disclosed.

### CROSS-REFERENCE TO RELATED APPLICATIONS

This application claims priority to U.S. Provisional Application No. 63/663,892, filed Jun. 25, 2024, entitled “CROWDOTIC: A PRIVACY-PRESER VING HOSPITAL WAITING ROOM CROWD DENSITY ESTIMATION”. The disclosure of which is incorporated herein by reference in their entirety.

### TECHNICAL FIELD

The present disclosure generally relates to intelligent air purification systems.

### BACKGROUND

The concentration of various airborne particles can affect the safety and comfort of individuals in spaces, such as indoor or enclosed spaces. Although some indoor spaces can use air purification systems including ultraviolet air sanitizers, filters, and/or the like, existing techniques for indoor air purifiers do not adequately consider the complex dynamic flow variations in particle concentration resulting from for example a human respiratory event, such as a cough, sneeze, or other type of event.

### SUMMARY

In some example embodiments, there is provided a system configured to receive an indication of an aerosol event at a first compartment of a room, wherein the room is divided into a plurality of compartments; receive, from at least one particulate measurement sensor located in the room and during a machine learning training phase, at least one particulate measurement for at least one compartment of the plurality of compartments of the room; train, during the machine learning training phase, a digital twin using aerosol event parameters comprising the indication of the aerosol event at the first compartment of the room and the at least one particulate measurement for the at least one of the plurality of compartments of the room; and provide the predicted concentration.

One or more of the following variations (as well as variations disclosed in the detailed description) may be provided as well. The digital twin may include a compartment model and a machine learning model, wherein the compartment model predicts, based on physical properties, concentration of aerosol for the aerosol event through the plurality of compartments, and wherein the machine learning model, based on at least the compartment model's prediction, generates an output indicative of a predicted concentration in one or more of the plurality of compartments of the room. The digital twin (including the compartment model and the trained machine learning model) may, based at least on the received indication of the aerosol event, predict the concentration. The machine learning model may output an error prediction in the concentration predicted by the compartment model. The error prediction may be used to adjust the compartment model's prediction of the concentration. The providing may include providing the adjusted prediction of concentration to direct the remediation action for the aerosol event. The adjusted prediction may further include a location in the room and the remediation action comprises instructions to cause an agent to perform the remediation action at the location. The agent may be a mobile agent comprising a filter, a fan, and/or an ultraviolet light, wherein the remediation action comprises sending instructions to filter air using the filter, activate the fan, and/or activate the ultraviolet light. The aerosol event may be simulated by an agent located in the room. The training may further include using a plurality aerosol event parameters collected from a plurality of compartments in the room and continuing the training until weights of the machine learning model converge. The machine learning model may include a long short-term memory model and graph convolution layer model, wherein the long short-term memory model and the graph convolution layer model capture spatiotemporal information in the plurality of aerosol event parameters. One or more aerosol detection parameters (which are obtained from a human in the room) may be received from a detection platform. The trained digital twin may generate one or more parameters indicative of a concentration prediction and/or a remediation action. A quantity of people present in the room may be estimated using non-speech audio to preserve privacy. The aerosol event may include a cough event and/or a sneeze event. The digital twin may be configured based at least in part on a surrogate machine leaning model representing computational fluid dynamics (CFD) simulation of a plurality of aerosol events.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 depicts an example of a system for intelligent air purification, in accordance with some embodiments;

FIG. 2A depicts an example implementation of a cough agent, in accordance with some embodiments;

FIG. 2B depicts an example of the purification agent, in accordance with some embodiments;

FIG. 2C depicts an example of a compartmented room, in accordance with some embodiments;

FIG. 3 depicts an example implementation of a digital twin comprising a compartment model and a machine learning model, in accordance with some embodiments;

FIG. 4 depicts an example of a process, in accordance with some embodiments;

FIG. 5 depicts an example of a process for a purification agent, in accordance with some embodiments; and

FIG. 6 depicts an example of a computing system, in accordance with some embodiments.

### DETAILED DESCRIPTION

The concentration of various airborne particles can, as noted, impact quality of life including comfort, health, safety, and quality of life. Although air purification systems including heating ventilation and air conditioning systems may use devices, such as filters, sanitizers, and/or the like, there is a challenge with respect to providing adaptive, autonomous systems that provide air purification. Indeed, there is a need to train such systems. But there is a lack of data to train models that can, for example, predict aerosol concentrations (e.g., dispersion over time and/or concentration over time) for an event, such as a cough event. Moreover, the associated computation flow dynamics (CFD) simulations for the event can require significant resources including substantial amounts of data.

In some embodiments, there is provided a digital twin model comprising a hybrid physics-machine learning model. The digital twin provides a model of the flow dynamics (e.g., dispersion and concentration at a given point in a room at a given point in time) for an event, such as a cough event.

In some embodiments, there is provided robotic cough events generator (also referred to herein as a “cough agent”) that simulates cough events and thus provides data that can be used to train the digital twin.

In some embodiments, there is provided control of an air purification device, such as a mobile air purifier (also referred to herein as a “purification agent”), that can be controlled to mitigate a coughing event at a specific location and time. Moreover, the air purification device, such as the mobile air purifier, may be used in conjunction with the cough agent to generate training data to train the digital twin to learn the flow dynamics of a room for example (e.g., cough aerosol concentration at a given location in a room at a given time).

In some embodiments, the digital twin comprises a physics-based component model and a machine learning (ML model). The physics-based component model refers to a physics-based model that predicts cough aerosol diffusion through a space. The ML model may comprise for example a long-term short memory ML model and graph convolutional layers (GC layers).

In some embodiments, the output of the digital twin (when trained) provides control information, such as a location and/or concentration of aerosol dispersion, to cause a purification system, such as a purification agent, to remediate the cough event. For example, a purification agent comprising a HEPA filter may be directed to move to a location in a room where the cough aerosol is present and/or take an action (e.g., activate a HEPA filter, or an HVAC intake vent to address the aerosol concentration at the location).

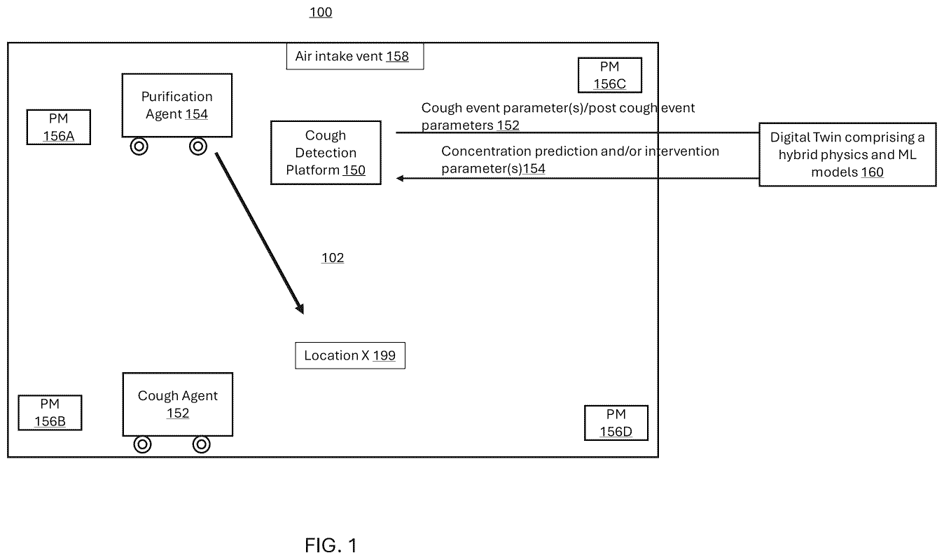

FIG. 1 depicts an example system 100 including at least one cough agent 152, a purification agent 154, a cough detection platform 150, and a digital twin 160, in accordance with some embodiments. The system 100 may also include one or more particulate matter (PM sensors, such as particulate matter sensors 156A-D.

Although some of the examples refer to cough as the syndrome being detected, other types of syndromic events may be detected as well (e.g., a sneeze, a body temperature using for example a thermal camera, crowd density, and/or the like).

Moreover, although some of the examples refer to a “room”, the system 100 may be implemented other types of enclosed or semi-enclosed spaces, and the system may be implemented in multiple rooms or spaces (e.g., an office building, a warehouse, a barn, etc.).

The cough agent 152 may be a mobile device, such as an autonomous ground vehicle (AGV), that is configured to move around the room 102 while generating cough events. For example, the cough agent may generate a cough event by expelling an aerosol, such as a mist or fog at one or more locations in the room.

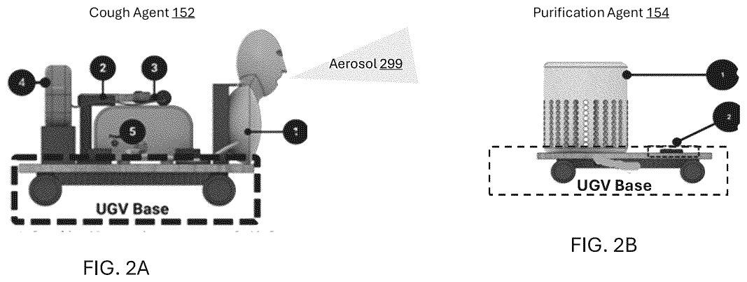

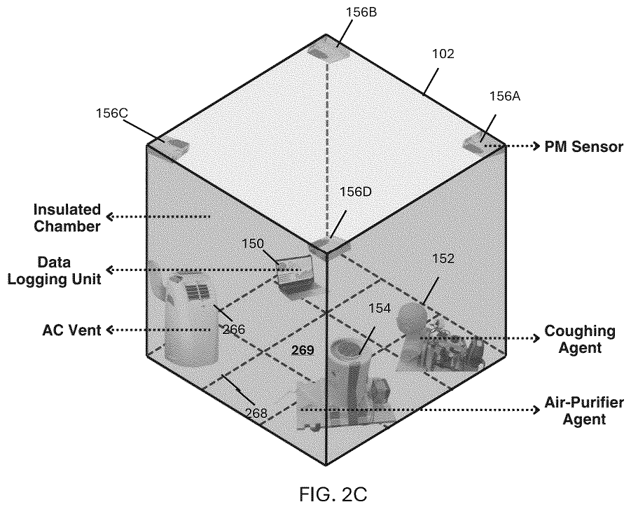

FIG. 2A depicts an example implementation of the cough agent 152. Referring to FIG. 2A, the cough agent 152 may include a cough mannequin (1), a linear actuator (2), an air compressor (3), an air compressor trigger (4), and a fog machine (5), all of which is mounted on an unmanned ground vehicle (UGV) base, such that the cough agent can move throughout the room 102. In operation, the UGV base may move the cough agent 152 to one or more locations within the room 102, while at a given location, the air compressor trigger may activate the linear actuator such that the air compressor provides pressure to force a “fog” to disperse as an aerosol 299 out of an opening in the mannequin. This fog simulates a person's cough and thus provides training data for a simulated cough event.

The example implementation of the robotic mannequin (which is comprised in the cough agent 152) may replicate human cough properties with a high fidelity and may produce cough events lasting 0.9 to 1.0 seconds with a cough flow rate of 2.6 liter/second, cough volume ranging from 1.8 to 2.4 liters, a mouth size of 3.8 cm², and a horizontal cough distance of 2.5 meters. Additionally, particle sizes produced by the cough agent 152 may be categorized into bins of 1.0, 2.5, 4.0, and 10.0 microns.

FIG. 2B depicts an example of the purification agent 154. Like the cough agent 152, the purifier agent may be a mobile. In the example of FIG. 2B, the purification agent includes an air purifier, such as a HEPA filter or other device (e.g., UV light, PM sensor, fan, etc.), and an electronics subsystem configured to control and/or maneuver the position of the agent, adjust fan speed of the air purifier, obtain PM sensor readings, receive commands or instructions to maneuver to a location, on-device model inference (e.g., host a version of the digital twin 160), communication circuitry (e.g., WiFi of other type of communications circuitry), and/or host applications, such as mobile apps or dashboard for user input.

During a training phase of operation, the purification agent 154 may be moved to a location and activated (e.g., activate a filter or other type of purification device), such that a particulate matter (PM) sensor can monitor and/or measure particle concentrations for the cough event aerosol at different locations in the room. This data may be provided along with other data to train the digital twin 160.

In an operational (e.g., inference) phase using the trained digital twin, when a person coughs in the room 102, the digital twin predicts the concentration of the cough aerosol in the room 102 and causes the purification agent to move to a location (e.g., with the highest concentration) to remediate the aerosol (e.g., by activating a fan, a UV light, and/or other action).

Referring again to FIG. 1, the cough detection platform 150 (also referred to herein as a detection platform) may comprise at least one processor and at least one memory. The cough detection platform may be configured to at least collect training data for the digital twin, collect data from the agents, collect data from particle measurement devices 156A-D, control the agents within the room, detect an aerosol event (e.g., a cough event, a sneeze event, and/or the like), relay commands or instructions to an agent, such as the purification agent (e.g., move to a location or compartment within the room, take an action, etc.), and/or perform other operations.

In operation for example, the cough detection platform 150 may transform audio detected from one or more people in the room 102. The audio may be processed to filter out (or block) speech in the audio (which preserves privacy especially in privacy sensitive areas such as health care facilities or corporate environments). As such, the remaining audio may be processed to detect an acoustic signature of a cough, a sneeze, or other type of aerosol generating event. To illustrate further, a 4-channel microphone array may be used to detect a cough (including the cough location) as well as a presence of a person coughing.

Moreover, the cough detection platform 150 may also be coupled to one or more particulate matter (PM) sensors 156A-D. For example, the particulate matter sensors may be deployed at various locations throughout the room to measure aerosol concentrations related to an aerosol event, such as a cough event, a sneeze event, and/or the like. These sensors may measure for example mass (μg/m³), number concentrations (#/cm³) for particles sized 1.0, 2.5, 4.0, and 10.0 microns, and/or other measurements.

Although the purification agent 154 is depicted separately from the PM sensors 156A-D, one or more of the PM sensors may be included in or carried by the purification agent. Furthermore, although FIG. 1 depicts 4 PM sensors, other quantities of PM sensors may be used as well to cover a space.

Likewise, although FIG. 1 depicts a certain quantity of components (e.g., a purification agent, a cough agent, a cough detection platform, a digital twin, 4 PM sensors, etc.), other quantities of each of these components may also be implemented as well. Moreover, the configuration of components at FIG. 1 is an example, so other component configurations may be implemented as well. For example, the purification agent 154 may host at least a portion (if not all of) the cough detection platform 150 and/or the digital twin 160. In addition, one or more of the components (e.g., a purification agent, a cough agent, a cough detection platform, a digital twin, 4 PM sensors, etc.) or portions of the components may be integrated in, or coupled to, a larger system, such as a HVAC system or other type of environmental control system.

When a coughing event is detected by the cough detection platform 150 by the cough's audio signature for example, the cough event may be localized to a given location (e.g., a compartment) in the room 102. When this is the case, the cough event platform may read the particulate matter sensor's 156A-D measurements to assess the dispersion of a cough over time (e.g., from a source location of a cough throughout the room). The particulate matter sensor measurements over time for a given cough event (as well as the location of the cough event within the room) may be used as cough event parameters 152. Alternatively, or additionally, particulate matter sensor measurements may be collected before the cough event as well and used as, for example, training data (and provided as part of the cough event parameters 152). Alternatively, or additionally, other measures about the room, such as room size, temperature, vent locations, air flow velocities, furniture placement, and/or other aspect of the room, may be collected before and/or after the cough event and used as, for example, training data (and provided as part of the cough event parameters 152).

The cough event parameters 152 are provided, as noted, to the digital twin 160. The digital twin provides a model representing the room 102. Specifically, the digital twin provides a model configured to predict the dispersion (or dynamic flow) of a dispersion event, such as a cough event, over time. As used herein, the occurrence of a cough is a cough event. The aerosol concentration at a given location (e.g., a given compartment of the room) and at a given time in the room 102 may be predicted using the digital twin 160.

For example, the digital twin's 160 aerosol concentration prediction may indicate that the concentration at location X 199 is a certain value (or e.g., over a threshold concentration amount), so purification remediation or intervention may be needed. When this is the case, the intervention (e.g., provided by the prediction or intervention parameters 154) may be in the form of causing or instructing the purification agent 154 to move to the location X 199, where the purification agent can take a remediation action, such as activate a HEPA filter to filter the cough's aerosol, activate a UV filter, take a measurement (e.g., using a PM sensor or other device), and/or take some other form of action. Alternatively, or additionally, the prediction or intervention parameters 154 may cause an HVAC system to activate an air intake vent 158, activate a fan, and/or take other actions.

After the remediation, the particulate matter sensors 156A-D may make additional measurements associated with the cough event. Alternatively, or additionally, these additional measures may be feedback (e.g., at 152) to the digital twin 160 and thus provide post-remediation information, which can be used further train the digital twin.

In some embodiments, the room may compartmented (e.g., divided) into a grid, such as a 3 by 3 grid of compartments (e.g., a total of 9 compartments). The plurality of compartments may reduce the processing resources needed for the flow dispersion predictions. In the case of the 3 by 3 grid, each compartment location represents a possible location for the cough agent 152 or the purification agent 154.

FIG. 2C depicts an example of the room 102 “compartmented” as a 3 by 3 grid 268 as noted above. In the example of FIG. 2C, the particulate matter sensors 156A-D are dispersed throughout the room 102. Also depicted is an air conditioning unit and/or vent unit 266. During data collection for training of the digital twin for example, the location of the air purification agent 154, location of the cough agent 152, and configuration information regarding room 102 cooling (and/or ventilation) may be gathered by the cough detection platform 150 (or other data processing device). For each of these data collection instances, particle monitor concentrations/measurements are collected by the sensors 156A-D before and after a simulated cough event. This data is then provided to the digital twin 160 which learns how to predict a cough's concentration diffusion throughout the room 102 given the cough's location.

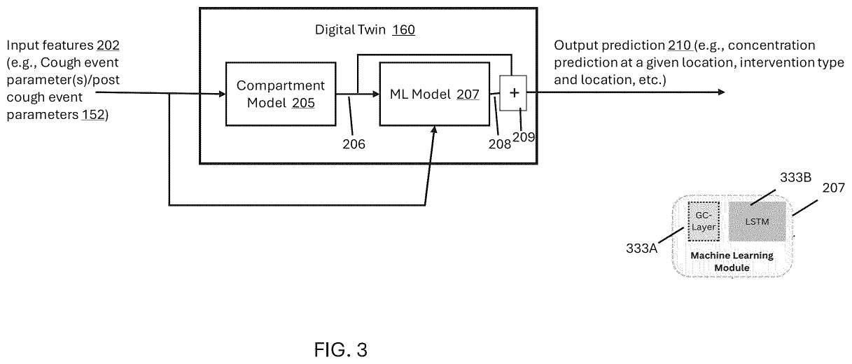

FIG. 3 depicts an example implementation of the digital twin 160, in accordance with some embodiments. The digital twin 160 comprises a compartment model 205 and a machine learning model 207.

The compartment model 205 may be used to model, using physics (e.g., physical properties), cough aerosol diffusion through a space, such as the room 102. The above-noted data collection (e.g., cough event parameter(s), post cough event parameters, and/or the like) may be used to train the digital twin 160. In the case of the compartment model 205, the above-noted data collection is used to configure the parameters of the compartment model 205. For example, the room may be divided into compartments, such as a 3 by 3 grid (although other compartment configurations may be used as well). The diffusion or flow dynamics among the compartments may be modeled using physics. To that end, the following equation may be used to capture the physical properties, such as the flow dynamics, among a plurality of compartments including the exchange of aerosol mass (denoted as Cᵢ) between compartments:

$${V}_{i} \frac{{dC}_{i}}{dt} = {\sum }_{j = 1}^{\vert {N}_{i} \vert} ( {α}_{j , i} \cdot {C}_{j} - {α}_{i , j} \cdot {C}_{i} ) - γ \cdot ω \cdot {C}_{i} - Q \cdot {C}_{i} + m$$

wherein
   Vᵢ is the volume of a compartment i;
   Cᵢ is particulate matter concentration in a compartment i;
   Nᵢ is the set of neighbor compartments of i where Cⱼ∈Nᵢ;
   αj, i is the outflow rate from a neighbor compartment j to i;
   m is the source aerosol release rate into a compartment i;
   [symbol] is the rate of exhaust output from compartment i;
   γ is the filter pollutant removal efficiency rate; and
   ω is the rate of air going through a filter unit in a compartment i.

The compartment model 205 assumes adjacency without diagonal connections.

The rate parameters may be learned using the collected data. In other words, the compartment model 205 outputs (given the cough event parameters) the diffusion (e.g., concentration of the particulate materials from a cough) for one or more compartments (at a given instance in time). Although the predicted output of the compartment model 205 may alone provide an indication of the concentration of a cough aerosol in each compartment of room 102, the compartment model alone may not provide sufficient accuracy to remediate the cough aerosol. As such, the digital twin 160 may further include the ML model 207.

The ML model 207 may be used in conjunction with the compartment model 205. In the example of FIG. 3, the compartment model 205 generates at 206 a prediction of the cough aerosol concentration at one or more compartments of the room 102.

In some embodiments, the ML model 207 learns to directly predict (at 208) using the compartment model's 205 output 206, the concentration in one or more (if not all) of the plurality of compartments of, for example, the room 102. This concentration information may be used to instruct a purification agent to move to a given compartment and take a remediation action, such as activate a fan or filter.

In some embodiments, the ML model learns to predict (at 208) an error in the compartment model's 205 prediction. The ML model's predicted error 208 is then used to adjust (e.g., remove) at 209 (e.g., using a summer or other logic) the error from the compartment model's prediction 206. In this way, the output prediction 210 indicates the cough aerosol concentration (as predicted by the compartment model 205 and error corrected by the ML model 207) in one or more of the plurality of compartments. This concentration information may be used to instruct a purification agent to move to a given compartment and take a remediation action, such as activate a fan or filter.

The following provides an example of the ML model 207 training. For example, the ML model 207 may be trained using collected data (e.g., cough event parameter information, information regarding the room 102, such as temperature, furniture placement, etc.), and the collected data may be based at least in part on simulated coughing events generated by the cough agent 152, for example. As noted, the cough agent simulates a cough that is measured by the PM sensors 158A-D and/or remediated by the purification agent 154. The ML model's training may include simulated coughs in some if not all of the plurality of compartments 268. To illustrate, the training data may include multiple PM sensor readings, ambient temperature, locations of the agents (e.g., the cough agent, purification agent, and/or PM sensors), and/or other information.

The ML model 207 may receive, as input, the same location and configuration information as the compartment model 205, such as which compartment is the origin of the cough event, room specific information (e.g., room dimensions, furniture placement, and/or the like), location of air purification agent 154, etc. The ML model 207 may also receive as an input the output 206 of the compartment model 205.

To adapt the ML model 205 to diverse conditions, the ML model 207 may be trained using first-order model agnostic meta-learning (MAML). MAML-based training comprises two phases. During the first phase, the ML model's parameters (e.g., weights) are randomly initialized. The training process involves multiple learning episodes, each representing a different potential scenario (e.g., various room and HVAC configurations, inclusion of air purifier, furniture arrangements, and locations of the coughing agent). The parameters of the ML model 207 are updated based on these learning episodes using variations of for example gradient descent-based optimization. During the second phase, the meta-trained ML model is introduced to a new, previously unseen configuration. The ML model parameters are then adapted for this new task relatively faster through a few gradient steps with limited data samples in few-shot learning manner.

To get a best possible accuracy from the compartment model 205, the corresponding parameters (e.g., air exchange between compartments and/or the like) may be re-estimated for each possible position of the purification agent, which may not be practical for some implementations. As such, the digital twin 160 may use a model configuration of an LSTM 333B and GC layer 333A (see, e.g., FIG. 3) may be used.

When the ML model 207 includes the LSTM 333B and the GC layer 333A, the LSTM GC layer may be used to provide a refinement (or fine tuning) of the output 206 of the compartment model 205 with default parameters, without re-estimation. This can be done by training the ML model's 207 modules (e.g., the GC layer 333A and the LSTM 333B) on the collected training data.

The Graph Convolution (GC) layer 333A is used to model spatial dependencies across the plurality of compartments, treating each compartment as a node in a graph and the edges between nodes defined similarly to the compartment model's neighborhood structure. The GC layer captures how connected compartments exchange mass based on airflow dynamics while independent of time.

The LSTM 333B is a recurrent neural network model that uses hidden and cell states maintained by different gates and is used to model the temporal evolution of the concentration dynamics. The LSTM-based model is configured for sequence-to-sequence prediction. The LSTM layer may include multiple layers (e.g., stacked LSTM). The inputs to the GC-LSTM modules comprise outputs 206 from the compartment model 205 and the additional collected data features (e.g., room information, cough information, etc.), such that the output 208 or 209 predicts the normalized PM concentrations directly or (2) indicates errors in the concentration (which is predicted by the compartment model in each of the multiple compartments).

As noted, the digital twin 160's ML model 207 may be configured to directly predict the PM concentration in one or more of the plurality of compartment or may be configured to predict an error in the PM concentration predicted by the compartment model 205. In either case, the features include syndromic detection (e.g., cough related information), space configuration (e.g., dimensions, vent locations, current HVAC parameters, etc.), and/or other collected data. These features may be used by compartment model 205 and the GC-LSTM layers 333A-B.

In some embodiments, the digital twin may incorporate computational fluid dynamics (CFD) simulations and surrogate machine learning models for concentration prediction and optimization processes as well. The surrogate ML models provide a ML substitute for the Stokes-based CFD simulations. In this way, the digital twin may be configured (or trained) based at least in part on a surrogate machine leaning model representing computational fluid dynamics (CFD) simulation of a plurality of aerosol events. CFD simulations may be used to estimate the parameters of compartment model 205 and to generate additional training data for the GC-LSTM module. These simulations may be used independently or may be used in combination with experimental data. Within a simulation module, syndromic events such as coughs are modeled to collect data on the dispersion dynamics and concentration of particulate matter (PM) across different room compartments over time. This simulation-generated data may then used to augment training datasets collected from physical coughing and purifier agents. The core process of the CFD module involves solving the transient, incompressible Navier-Stokes equations, which are coupled with advection-diffusion equations to model scalar quantities such as temperature and PM concentration. These equations account for the influence of buoyancy, aerosol source terms (e.g., a cough), and boundary conditions imposed by ventilation systems and static obstacles (e.g. furniture). To reduce computational requirements and enable faster simulations, surrogate neural network layers are selectively used. These surrogates (which may utilize neural network architectures such as U-Net, a convolutional neural network, etc.) approximate the solutions to the underlying physical equations and are pre-trained on datasets from existing CFD simulations. The choice of utilizing the faster surrogate model or the full numerical solver depends on variables such as room configuration; faster surrogate models may be used for environments similar to those already in the training data, while the full solver is reserved for configurations not included in the training data.

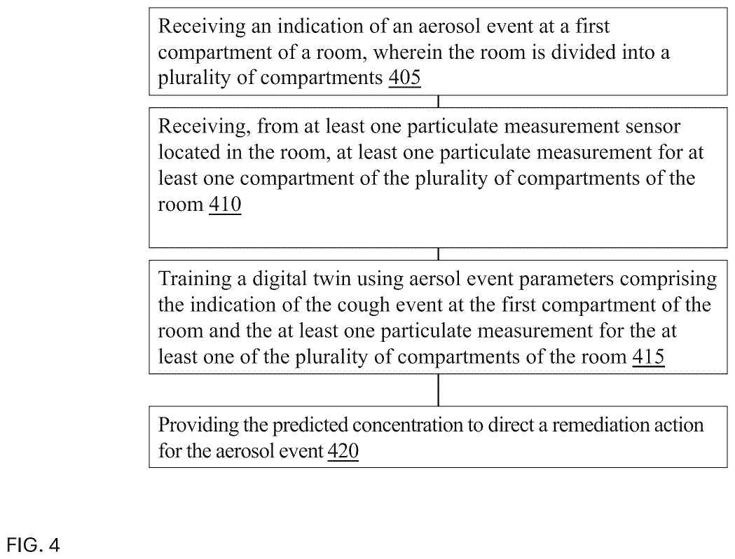

FIG. 4 depicts an example process 400 for intelligent air purification, in accordance with some embodiments.

At 405, the process 400 may include receiving an indication of an aerosol event, such as a cough event, sneeze event, and/or the like, at a first compartment of a room, wherein the room is divided into a plurality of compartments, in accordance with some embodiments. Referring to FIGS. 1 and 2C for example, when a cough or a sneeze occurs in one of the plurality of compartments 268 of the room 102 for example, the aerosol event may be detected by for example the detection platform 150 (or other component of system 100), and then the received indication may be forwarded or provided at 152 to at least the digital twin 160). As noted, the audio of the aerosol event may be detected and localized to a compartment using for an audio signature of the event and a 4-channel microphone array, although the event may be detected and localized in other ways as well. The cough or sneeze event may be simulated or an actual human's cough.

At 410, the process 400 may include receiving, from at least one particulate measurement sensor located in the room, at least one particulate measurement for at least one compartment of the plurality of compartments of the room, in accordance with some embodiments. Referring to FIGS. 1 and 2C for example, one or more of the PM sensors 156A-D may measure the particulate concentration of the cough event. The measurement(s) may be sent by the PM sensor(s) to for example a cough detection platform 150 (or another component of system 100). The measurements may be forwarded or provided to the digital twin 160. In some embodiments, some, if not all, of the 9 compartments 268 is measured for particulate concentration of the cough event (e.g., by a dedicated PM sensor in a given compartment and/or by a PM sensor mounted on a mobile agent, such as the purification agent 154 or other type of agent).

At 415, the process 400 may include training a digital twin using an aerosol event parameters (e.g., cough or sneeze event parameters) comprising the indication of the aerosol event at the first compartment of the room and the at least one particulate measurement for the at least one of the plurality of compartments of the room, in accordance with some embodiments. Referring to FIGS. 1 and 3 for example, the digital twin 160 may be trained using at least the cough event parameters 152 that include (1) the indication of the aerosol event, such as the cough event, and a location of the aerosol event (e.g., at a first compartment of the plurality of compartments) of the room 102 and (2) the particulate sensor measurements for the aerosol event. The particulate sensor measurements may be for some if not all of the compartments of the room.

During the training phase, the ML model 207 is trained as noted. In an inference phase, the input features may include aerosol event parameters (e.g., an indication of a cough or sneeze from a person and a compartment identifier (e.g., location in the room), such that the digital twin can provide an output prediction, such as a concentration prediction in one or more of the compartments and/or a remediation action.

At 420, the process 400 may include providing the predicted concentration to direct a remediation action for the aerosol event, in accordance with some embodiments. Referring to FIGS. 1 and 3 for example, the digital twin 160 may output a predicted concentration of the particulates in one or more if not all of the compartments of the room 102. For example, the predicted concentration may be sent at 154 to the detection platform 150 (or other component of system 100). Moreover, the predicted concentration may trigger a remediation action. For example, the predicted concentration may indicate that the concentration is highest at compartment 3 (see, e.g., 269 at FIG. 2C). When this is the case, an instruction may be sent at 154 for example to take a remediation action at compartment 3 by for example moving a purification agent 154 to compartment 3, activating a fan, and/or the like.

As noted, the digital twin 160 may include a compartment model 205 and a machine learning model 207. The compartment model may predict, based on physical properties, concentration of aerosol for the cough event through the plurality of compartments in the room. The machine learning model (based on at least the concentration of aerosol for the cough event through the plurality of compartments in the room provided by the component model) may generate an output indicative of a predicted concentration in one or more of the plurality of compartments of the room. As noted, the indication may be a direct indication of the predicted concentration or an error in the compartment model's prediction.

In the case the ML model 207 outputs an error in the compartment model's prediction, this error prediction is used to adjust the compartment model's prediction of the concentration. And, the adjusted prediction of concentration is use to direct the remediation action for the cough event. Moreover, the adjusted prediction may further include a location in the room where the remediation action should take place and instructions causing an agent to perform the remediation action at the location.

When the agent is a mobile agent as in the examples of FIGS. 2A and 2B, the agent may include a filter, a fan, and/or an ultraviolet light, such that the remediation action may include instructions to filter air using the filter, activate a fan, and/or activate an ultraviolet light. In some instances, the instructions are provided at 154 either directly to an agent or relayed (e.g., via the cough detection platform) to the agent.

Although some of the examples refer to a cough event, the event may be an aerosol event, such as a cough, sneeze, or other aerosol generation event. Moreover, the cough agent 152 may be configured to simulate other aerosol events as well, such as a sneeze event and/or the like. Likewise, the purification agent may remediate the aerosol event, while the PM sensor may measure the aerosol from the other aerosol generating event.

With respect to digital twin training or configuration, the cough event may be simulated by a cough agent, such as cough agent 152, located in the room. Moreover, a plurality cough event parameters may be collected from a plurality of compartments in the room, and the training may continue until the machine learning model's weights converge.

During the digital twin's inference operations, the digital twin may receive, from for example a cough detection platform or other component of system 100, one or more cough detection parameters obtained from an actual human in the room. Next, the digital twin may generate one or more parameters indicative of a concentration prediction and/or a remediation action.

### ADDITIONAL EXAMPLES

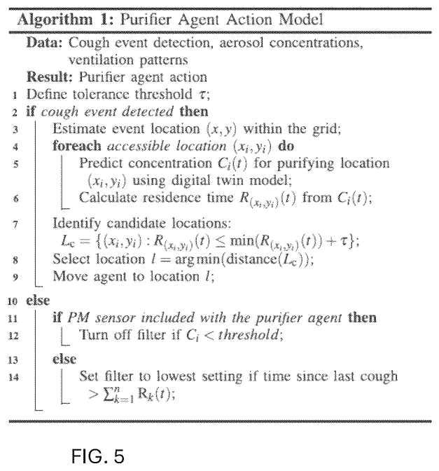

Referring again to FIGS. 1 and 2C, the digital twin 160 may drive the purifier agent's 154 placement strategy to for example minimize the cough aerosol's dwell time. For example, the purification agent 154 may autonomously move within the compartments 268 of the 3 by 3 grid of room 102 grid. When at a compartment (or within a specific grid), the purification agent 154 may remediate the cough aerosol at that compartment by for example adjusting fan speed (e.g., to optimize power usage and/or filter life), activating a HEPA filter or UV light, and/or taking other actions. FIG. 5 depicts an example simplified algorithm (“Algorithm 1”) for the purification agent 154, although other approaches may be used as well for the purification agent. At FIG. 5, cough events and grid-level localization inform the purification agent's 154 positioning by for example using an environment map of the room 102 that may include items, such as positions of vents, furniture, and/or other obstacles while the optimal agent 154 placement policy is determined using at least Algorithm 1 depicted at FIG. 5.

In some embodiments, the system 100 may estimate occupancy estimation within the room 102. For example, non-speech audio may be used in a room to estimate a quantity of people in the room. As noted above, the cough detection platform 150 may detect audio from one or more people in the room 102 but filter out (e.g., block) speech in the detected audio. This results in non-speech audio, so this preserves privacy especially in privacy sensitive areas such as a health care setting. The non-speech audio can be further processed to detect cough signature. Moreover, directional audio techniques (e.g., phase, angle of arrival, multiple audio sensors) may be used as well to detect the quantity of for example coughing subjects in the room 102.

To illustrate further, the privacy preserving audio of crowd size in room 102 may for example use audio as a sole data modality, as opposed to vision-based sensors such as cameras, to avoid visual surveillance. Moreover, the process may only process non-speech audio, as noted, by employing, among other things, a computationally efficient and highly accurate machine learning model that operates on-device (e.g., at the edge such as at the cough detection platform or other component at system 100). This model preemptively classifies and discards any audio segments containing human speech, ensuring such data is not transmitted to a server for additional processing. Further, the system may implement differential privacy as an additional technological safeguard. This technique systematically introduces statistical noise to the data, thereby mitigating the risk of re-identification attacks that could otherwise infer speaker identity or other sensitive attributes from non-speech audio signatures. Consequently, this process may provide robust and accurate occupancy estimation while upholding privacy standards. This occupancy estimation methodology may serve as an input for the dynamic control purification as disclosed herein. An advantage of this integration is its efficiency as the occupancy estimation can use the same non-speech audio data and a subset of the same machine learning models developed for the syndromic detection platform of the cough detection platform 150. The real-time occupancy data directly informs automated intervention strategies by allowing the system 100 to modulate for example building-wide HVAC parameters, such as adjusting fresh air intake in response to occupant load. Furthermore, the system may use this information to formulate mitigation actions that minimize undue disturbance. For instance, a mobile purification unit can be strategically directed to operate in an adjacent, unoccupied area, rather than being moved directly into a populated space where its operation might disturb the occupants.

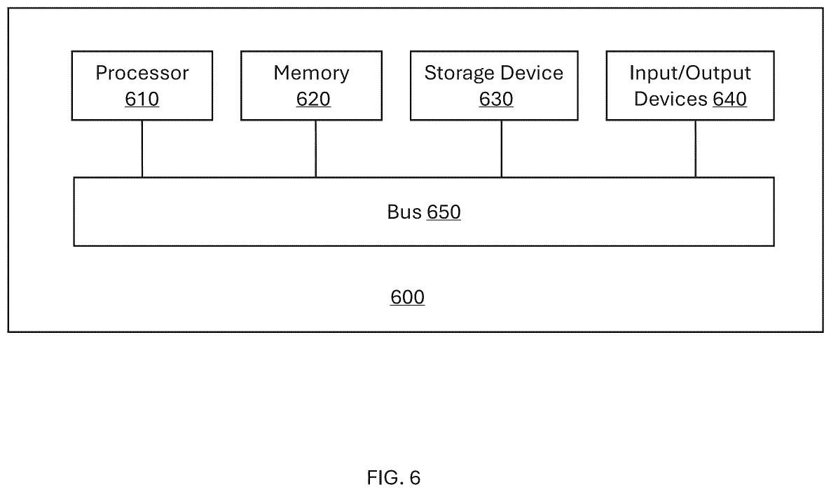

FIG. 6 depicts a block diagram illustrating a computing system 600 consistent with implementations of the current subject matter. Referring to FIGS. 1-5, the computing system 600 can be used to implement the processes disclosed herein (e.g., at FIGS. 1-5 and/or the like). Alternatively, or additionally, the computing system 600 may be comprised at least in part in the electronics circuitry, such as the cough detection platform 150, digital twin 160, cough agent 152, purification agent 154, particulate sensors 156A-D, and/or the like. 112. Alternatively, or additionally, the computing system 600 may be coupled to the system 100.

As shown in FIG. 6, the computing system 600 can include a processor 610, a memory 620, a storage device 630, and input/output devices 640. The processor 610, the memory 620, the storage device 630, and the input/output devices 640 can be interconnected via a system bus 650. The processor 610 is capable of processing instructions for execution within the computing system 600. In some implementations of the current subject matter, the processor 610 can be a single-threaded processor. Alternately, the processor 610 can be a multi-threaded processor. Alternately, the processor 610 may be a graphics processing unit, an artificial intelligence processor (e.g., configured to handle neural networks and other ML models). The processor 610 is capable of processing instructions stored in the memory 620 and/or on the storage device 630 to display graphical information for a user interface provided via the input/output device 640.

The memory 620 is a computer readable medium such as volatile or non-volatile that stores information within the computing system 600. The memory 620 can store data structures, instruction, code, and/or the like. The storage device 630 is capable of providing persistent storage for the computing system 600. The storage device 630 can be a solid-state device, a hard disk device, an optical disk device, and/or any other suitable persistent storage means. The input/output device 640 provides input/output operations for the computing system 600. In some implementations of the current subject matter, the input/output device 640 includes a keyboard and/or pointing device. In various implementations, the input/output device 640 includes a display unit for displaying graphical user interfaces.

According to some implementations of the current subject matter, the input/output device 640 can provide input/output operations for a network device. For example, the input/output device 640 can include Ethernet ports or other networking ports to communicate with one or more wired and/or wireless networks (e.g., a local area network (LAN), a wide area network (WAN), the Internet).

One or more aspects or features of the subject matter described herein can be realized in digital electronic circuitry, integrated circuitry, specially designed ASICs, field programmable gate arrays (FPGAs) computer hardware, firmware, software, and/or combinations thereof. These various aspects or features can include implementation in one or more computer programs that are executable and/or interpretable on a programmable system including at least one programmable processor, which can be special purpose (e.g., AI or ML specialized processors) or general purpose, coupled to receive data and instructions from, and to transmit data and instructions to, a storage system, at least one input device, and at least one output device.

These computer programs, which can also be referred to as programs, software, software applications, applications, components, or code, include machine instructions for a programmable processor, and can be implemented in a high-level procedural and/or object-oriented programming language, and/or in assembly/machine language. As used herein, the term “machine-readable medium” refers to any non-transitory computer readable storage medium, program product, apparatus and/or device, such as for example magnetic discs, optical disks, memory, and Programmable Logic Devices (PLDs), used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example, as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including acoustic, speech, or tactile input. Other possible input devices include touch screens or other touch-sensitive devices such as single or multi-point resistive or capacitive track pads, voice recognition hardware and software, optical scanners, optical pointers, digital image capture devices and associated interpretation software, and the like.

The subject matter described herein can be embodied in systems, apparatus, methods, and/or articles of manufacture depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. For example, the logic flows may include different and/or additional operations than shown without departing from the scope of the present disclosure. One or more operations of the logic flows may be repeated and/or omitted without departing from the scope of the present disclosure. Other implementations may be within the scope of the following claims.

Although ordinal numbers such as first, second and the like can, in some situations, relate to an order; as used in a document ordinal numbers do not necessarily imply an order. For example, ordinal numbers can be merely used to distinguish one item from another. For example, to distinguish a first event from a second event, but need not imply any chronological ordering or a fixed reference system (such that a first event in one paragraph of the description can be different from a first event in another paragraph of the description).

The foregoing description is intended to illustrate but not to limit the scope of the invention, which is defined by the scope of the appended claims. Other implementations are within the scope of the following claims.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and sub-combinations of the disclosed features and/or combinations and sub-combinations of several further features disclosed above. In addition, the logic flows depicted in the accompanying figures and/or described herein do not necessarily require the particular order shown, or sequential order, to achieve desirable results. Other implementations can be within the scope of the following claims.

What is claimed:

1. A system comprising:
at least one processor; and
at least one memory including instructions which when executed by the at least one processor cause operations comprising:
receiving an indication of an aerosol event at a first compartment of a room, wherein the room is divided into a plurality of compartments;
receiving, from at least one particulate measurement sensor located in the room and during a machine learning training phase, at least one particulate measurement for at least one compartment of the plurality of compartments of the room;
training, during the machine learning training phase, a digital twin using aerosol event parameters comprising the indication of the aerosol event at the first compartment of the room and the at least one particulate measurement for the at least one of the plurality of compartments of the room; and
providing the predicted concentration.

2. The system of claim 1, wherein the digital twin includes a compartment model and a machine learning model, wherein the compartment model predicts, based on physical properties, concentration of aerosol for the aerosol event through the plurality of compartments, and wherein the machine learning model, based on at least the compartment model's prediction, generates an output indicative of a predicted concentration in one or more of the plurality of compartments of the room.

3. The system of claim 1 further comprising: using, based at least on the received indication of the aerosol event, the digital twin including the compartment model and the trained machine learning model to predict the concentration.

4. The system of claim 1, wherein the machine learning model outputs an error prediction in the concentration predicted by the compartment model.

5. The system of claim 4, wherein the error prediction is used to adjust the compartment model's prediction of the concentration.

6. The system of claim 5, wherein the providing comprises providing the adjusted prediction of concentration to direct the remediation action for the aerosol event.

7. The system of claim 5, wherein the adjusted prediction further includes a location in the room and the remediation action comprises instructions to cause an agent to perform the remediation action at the location.

8. The system of claim 7, wherein the agent is a mobile agent comprising a filter, a fan, and/or an ultraviolet light, wherein the remediation action comprises sending instructions to filter air using the filter, activate the fan, and/or activate the ultraviolet light.

9. The system of claim 1, wherein the aerosol event is simulated by an agent located in the room.

10. The system of claim 1, wherein the training further comprises:
using a plurality aerosol event parameters collected from a plurality of compartments in the room and continuing the training until weights of the machine learning model converge.

11. The system of claim 1, wherein the machine learning model comprises a long short-term memory model and graph convolution layer model, wherein the long short-term memory model and the graph convolution layer model capture spatiotemporal information in the plurality of aerosol event parameters.

12. The system of claim 1 further comprising:
receiving, from a detection platform, one or more aerosol detection parameters obtained from a human in the room;
generating, by the trained digital twin, one or more parameters indicative of a concentration prediction and/or a remediation action.

13. The system of claim 1, further comprising estimating a quantity of people present in the room using non-speech audio to preserve privacy.

14. The system of claim 1, wherein the aerosol event comprises a cough event and/or a sneeze event.

15. The system of claim 1, wherein the digital twin is configured based at least in part on a surrogate machine leaning model representing computational fluid dynamics (CFD) simulation of a plurality of aerosol events.

16. A method comprising:
receiving an indication of an aerosol event at a first compartment of a room, wherein the room is divided into a plurality of compartments;
receiving, from at least one particulate measurement sensor located in the room and during a machine learning training phase, at least one particulate measurement for at least one compartment of the plurality of compartments of the room;
training, during the machine learning training phase, a digital twin using aerosol event parameters comprising the indication of the aerosol event at the first compartment of the room and the at least one particulate measurement for the at least one of the plurality of compartments of the room; and
providing the predicted concentration.

17. The method of claim 16, wherein the digital twin includes a compartment model and a machine learning model, wherein the compartment model predicts, based on physical properties, concentration of aerosol for the aerosol event through the plurality of compartments, and wherein the machine learning model, based on at least the compartment model's prediction, generates an output indicative of a predicted concentration in one or more of the plurality of compartments of the room.

18. The method of claim 16 further comprising: using, based at least on the received indication of the aerosol event, the digital twin including the compartment model and the trained machine learning model to predict the concentration.

19. The method of claim 16, wherein the machine learning model outputs an error prediction in the concentration predicted by the compartment model.

20. A non-transitory computer readable storage medium instructions which when executed by at least one processor cause operations comprising:
receiving an indication of an aerosol event at a first compartment of a room, wherein the room is divided into a plurality of compartments;
receiving, from at least one particulate measurement sensor located in the room and during a machine learning training phase, at least one particulate measurement for at least one compartment of the plurality of compartments of the room;
training, during the machine learning training phase, a digital twin using aerosol event parameters comprising the indication of the aerosol event at the first compartment of the room and the at least one particulate measurement for the at least one of the plurality of compartments of the room; and
providing the predicted concentration.
